(19) United States
(12) Patent Application Publication
(10) Pub. No.: US 2026/0066242 A1
(43) Pub. Date: Mar. 5, 2026

(54) PLASMA GENERATING APPARATUS

(71) Applicant: Samsung Electronics Co., Ltd., Suwon-si (KR)

(72) Inventors: Seongyeop Jeong, Suwon-si (KR); DAE WEE KONG, Suwon-si (KR); Youngsu Noh, Suwon-si (KR); Jingyu Park, Suwon-si (KR); Mingyo Byeon, Suwon-si (KR); MYUNG MO AHN, Suwon-si (KR); Byeongsun Yoo, Suwon-si (KR)

(21) Appl. No.: 19/061,081

(22) Filed: Feb. 24, 2025

(30) Foreign Application Priority Data
Sep. 4, 2024 (KR) 10-2024-0120176

(51) Int. Cl. H01J 37/32

(52) U.S. Cl. CPC H01J 37/32669; H01J 37/32568; H01J 2237/3323

(57) ABSTRACT

A plasma generating apparatus according to an embodiment includes a plasma chamber, a pair of opposed electrodes installed inside the plasma chamber and forming an electric field to generate plasma by applying an AC voltage, and a solenoid coil surrounding a sidewall of the plasma chamber and supplying a DC current to form a magnetic field, wherein a part of the magnetic field formed by the solenoid coil penetrates the opposed electrodes.

### CROSS-REFERENCE TO RELATED APPLICATION

This application claims priority under 35 U.S.C. § 119 to and the benefit of Korean Patent Application No. 10-2024-0120176, filed in the Korean Intellectual Property Office on Sep. 4, 2024, the entire contents of which are incorporated herein by reference.

### BACKGROUND

### 1. Field

The present disclosure concerns a plasma generating apparatus. More particularly, the present disclosure relates to a plasma generating apparatus generating plasma.

### 2. Description of the Related Art

Semiconductor devices can be manufactured by various semiconductor manufacturing processes, such as an etching process, a deposition process, an ashing process, or a cleaning process.

The plasma generating apparatus used in semiconductor device manufacturing processes includes a capacitively coupled plasma (CCP) structure forming an electric field between a pair of opposed electrodes to generate plasma, and an inductively coupled plasma (ICP) structure forming an induced electric field by winding a coil outside the plasma chamber to generate plasma. Particularly, in a capacitively coupled plasma (CCP) structure, a relatively strong electric field is applied to an edge region of a wafer located inside the plasma chamber. In this case, plasma density may be different at the center and an edge region of the wafer. Therefore, the uniformity of the film formed on the wafer may be deteriorated.

### SUMMARY

The present disclosure attempts to provide a plasma generating apparatus capable of improving the uniformity of the electron density of plasma and thereby improving the uniformity of the film formed on the substrate.

A plasma generating apparatus according to an embodiment includes a plasma chamber, a pair of opposed electrodes installed inside the plasma chamber and forming an electric field to generate plasma by applying AC voltage, and a solenoid coil surrounding a sidewall of the plasma chamber and supplying DC current to form a magnetic field, wherein a part of the magnetic field formed by the solenoid coil penetrates the opposed electrodes.

A plasma generating apparatus according to another embodiment includes a plasma chamber, a pair of opposed electrodes installed inside the plasma chamber and forming an electric field to generate plasma by applying AC voltage, and a solenoid coil surrounding a sidewall of the plasma chamber and supplying DC current to form a magnetic field, an AC voltage supply applying the AC voltage to the pair of opposed electrodes, and a DC current supply supplying the DC current to the solenoid coil, wherein a direction of a part of the magnetic field, which penetrates the opposed electrode among the magnetic field formed by the solenoid coil, is perpendicular to surfaces of the opposed electrodes.

A plasma generating apparatus according to another embodiment includes a plasma chamber, a pair of opposed electrodes installed inside the plasma chamber and forming an electric field to generate plasma by applying AC voltage, and a solenoid coil surrounding a sidewall of the plasma chamber and supplying DC current to form a magnetic field, wherein an imaginary central axis of the solenoid coil is positioned on the same line as the centers of the pair of opposed electrodes.

According to embodiments, the uniformity of electron density of plasma adjacent to the substrate can be improved by installing a pair of opposed electrodes inside the plasma chamber, applying AC voltage to the opposed electrodes to generate an electric field between the opposed electrodes, installing a solenoid coil on the sidewall of the plasma chamber and supplying DC current to the solenoid coil to generate a magnetic field parallel to the electric field.

Therefore, the uniformity of the film formed on the substrate positioned inside the plasma chamber can be improved.

### BRIEF DESCRIPTION OF THE DRAWINGS

FIG. 1 is a schematic perspective view of a plasma generating apparatus according to an example embodiment.

FIG. 2 is a schematic cross-sectional view of a plasma generating apparatus according to an example embodiment.

FIG. 3 illustrates the direction of the DC current and the direction of the magnetic field in the plasma generation apparatus of FIG. 2.

FIG. 4 illustrates the direction of the electric field and the direction of the magnetic field generated in the plasma generating apparatus of FIG. 2.

FIG. 5 illustrates the electron density of plasma generated in the plasma generating apparatus of FIG. 2 when no magnetic field is generated.

FIG. 6 illustrates the electron density of plasma generated in the plasma generating apparatus of FIG. 2 when a magnetic field is generated.

FIG. 7 is a graph of the minimum magnetic field strength required to magnetize electrons inside the plasma chamber according to the pressure inside the plasma chamber in the plasma generation apparatus of FIG. 2.

FIG. 8 is a schematic a cross-sectional view of a plasma generating apparatus according to another example embodiment.

### DETAILED DESCRIPTION OF THE EMBODIMENTS

Hereinafter, with reference to accompanying drawings, various embodiments of the present disclosure will be described in detail so that a person of an ordinary skill can easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown. In the drawings, the thickness of layers, films, panels, regions, etc., are exaggerated for clarity. And in the drawings, for convenience of explanation, the thicknesses of some layers and regions are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “a plane view”, it means that the target portion is viewed from above, and when referring to “a cross-sectional view”, it means that a cross section of the target portion cut vertically is viewed from a side.

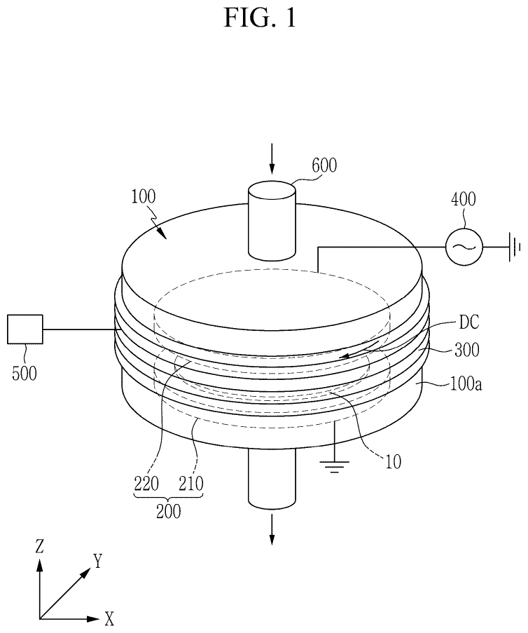

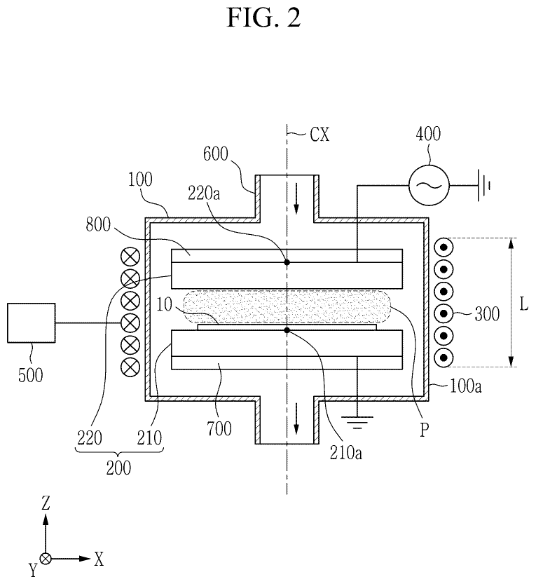

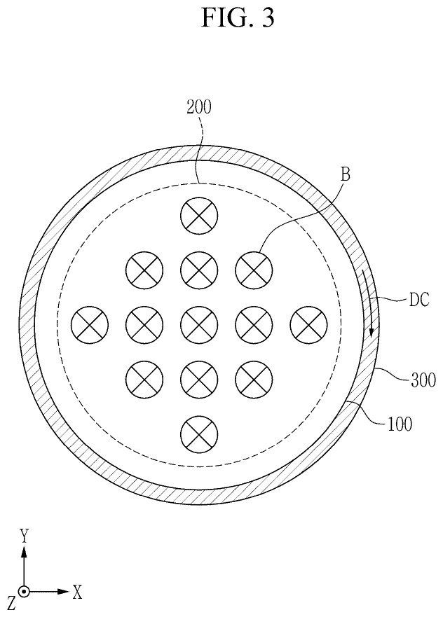

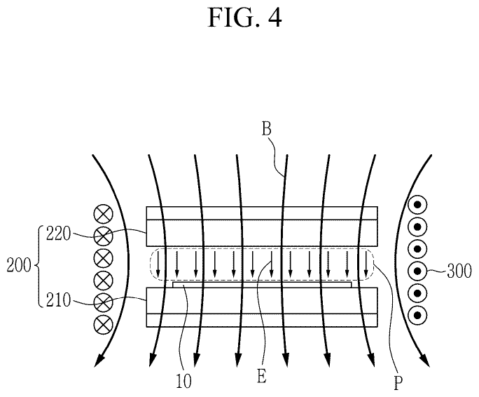

FIG. 1 is a schematic perspective view of a plasma generating apparatus according to an example embodiment, FIG. 2 is a schematic cross-sectional view of FIG. 1, FIG. 3 illustrates the direction of the DC current and the direction of the magnetic field in the plasma generation apparatus of FIG. 2, and FIG. 4 illustrates the direction of the electric field and the direction of the magnetic field generated in the plasma generating apparatus of FIG. 2.

As shown in FIG. 1 to FIG. 4, a plasma generating apparatus according to an embodiment of the present disclosure includes a plasma chamber 100, a pair of opposed electrodes 200, a solenoid coil 300, an AC voltage applying unit 400, a DC current supply unit 500, a gas supply unit 600, a heater 700, and a shower head 800.

The plasma chamber 100 has a roughly cylindrical shape, and the sidewall 100a of the plasma chamber 100 may be a cylindrical surface. For example, the sidewall 100a of the plasma chamber 100 may form a cylindrical surface. In this way, since the sidewall 100a of the plasma chamber 100 is a cylindrical surface, the solenoid coil 300 may be installed surrounding the sidewall 100a of the plasma chamber 100. For example, the solenoid coil 300 may be on an external side of the sidewall 100a of the plasma chamber 100. As another example, the solenoid coil 300 may be on an internal side of the sidewall 100a of the plasma chamber 100.

Plasma (P) is generated inside the plasma chamber 100 and may be applied to the substrate 10, which is a target of plasma treatment. Here, the substrate 10 may be a wafer.

The pair of opposed electrodes 200 is installed inside the plasma chamber 100, and an electric field E may be formed by applying AC voltage to generate plasma P.

The pair of opposed electrodes 200 may include a first electrode 210 and a second electrode 220 that are spaced apart from each other by a predetermined interval and opposed in parallel. Each of the first electrode 210 and the second electrode 220 may have a circular disc shape. An electric field E may be formed in the vertical direction (Z) between the first electrode 210 and the second electrode 220 by applying AC voltage to the first electrode 210 and the second electrode 220. At this time, plasma P may be generated by applying the electric field E to gas such as a plasma source or reaction gas supplied through the gas supply unit 600. This plasma generating structure is called a capacitively coupled plasma (CCP) structure. At this time, the first electrode 210 may function as a support on which the substrate 10 is settled.

The solenoid coil 300 surrounds the sidewall 100a of the plasma chamber 100 and may form a magnetic field B by applying a DC current DC from the DC current supply unit 500. The solenoid coil 300 may be positioned on the outer surface of the sidewall 100a of the plasma chamber 100. The solenoid coil 300 may have a length L in the vertical direction (Z). As shown in FIG. 3, when DC current DC flows in a clockwise direction, a magnetic field B may be formed in a direction (−Z) penetrating the pair of opposed electrodes 200.

The imaginary center axis CX of the solenoid coil 300 may be positioned on the same line as the centers 210a and 220a of the first electrode 210 and the second electrode 220, respectively. Therefore, a uniform magnetic field B may be formed in all regions of the first electrode 210 and the second electrode 220.

Additionally, the solenoid coil 300 may include a conductor solenoid coil made of a conductor material having resistance or a superconductor solenoid coil made of a superconductor material having no resistance at a specific temperature. When the solenoid coil 300 is made of a superconductor solenoid coil, the strength of the DC current DC can be increased to the maximum so that a magnetic field B of 1 Tesla or more can be formed.

In addition, when the solenoid coil 300 is made of a superconductor solenoid coil, not only electrons but also large-sized particles such as ions and particles can be magnetized and controlled since a magnetic field B of 1 Tesla or more is formed.

The AC voltage applying unit 400 is electrically connected to the pair of opposed electrodes 200 and can apply AC voltage to the pair of opposed electrodes 200. Here, the AC voltage may be a radio frequency (RF) voltage. The AC voltage applying unit 400 may also be referred to as an AC voltage supply.

The DC current supply unit 500 is electrically connected to the solenoid coil 300 and may supply DC current DC to the solenoid coil 300. The DC current supply unit 500 may also be referred to as a DC current supply.

Therefore, a part of the magnetic field B formed by the solenoid coil 300 may penetrate the opposed electrodes 200. For example, the direction of a part of the magnetic field B formed by the solenoid coil 300, which penetrates the opposed electrodes 200, may be perpendicular to the surface of the opposed electrodes 200.

Therefore, as shown in FIG. 4, the direction of some of the magnetic field B formed by the solenoid coil 300, which penetrates the opposed electrodes 200, may be parallel to the direction of the electric field E formed by the opposed electrodes 200.

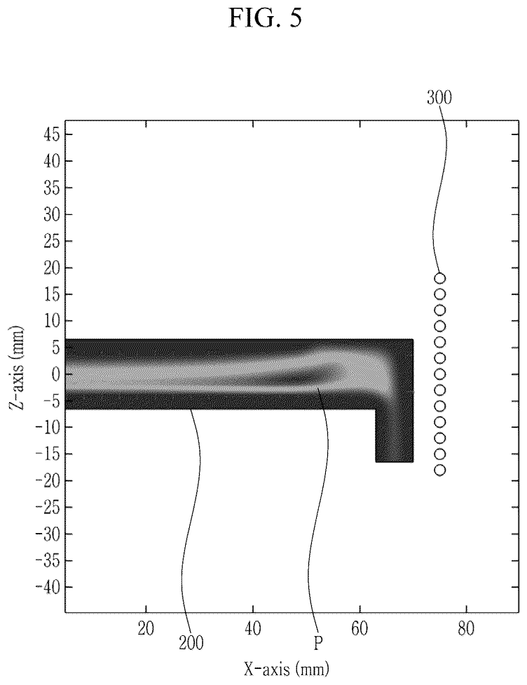

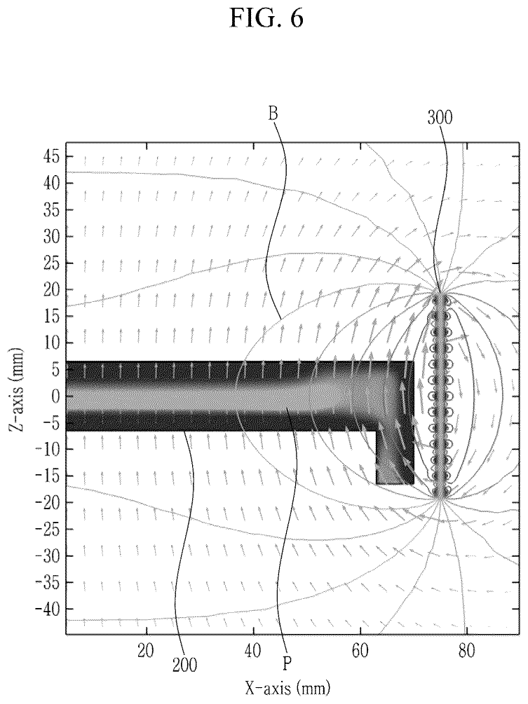

FIG. 5 and FIG. 6 illustrate the electron density of plasma generated in the plasma generating apparatus of FIG. 2. FIG. 5 illustrates the electron density of plasma generated in the plasma generating apparatus of FIG. 2 when no magnetic field is generated, and FIG. 6 illustrates the electron density of plasma generated in the plasma generating apparatus of FIG. 2 when a magnetic field is generated. Here, the units of X-axis and Y-axis are millimeters (mm).

As shown in FIG. 5, it can be seen that the electron density of the plasma P is non-uniform when a magnetic field B perpendicular to the pair of opposed electrodes 200 is not formed.

However, as shown in FIG. 6, if a magnetic field B perpendicular to the pair of opposed electrodes 200 is formed, it can be seen that the electrons adjacent to the substrate 10 are magnetized by the magnetic field B and the electron density of the plasma P adjacent to the substrate 10 becomes uniform.

In this way, by installing a pair of opposed electrodes 200 inside the plasma chamber 100, applying AC voltage to the opposed electrodes 200 to generate an electric field E between the opposed electrodes 200, installing a solenoid coil 300 on the sidewall 100a of the plasma chamber 100, and supplying DC current DC to the solenoid coil 300 to generate a magnetic field B parallel to the electric field E, the uniformity of the electron density of the plasma P adjacent to the substrate 10 can be improved.

Meanwhile, the gas supply unit 600 may supply gases such as plasma source and reaction gas to the inside of the plasma chamber 100. The reaction gas may include hydrogen H2, oxygen O2, oxidation carbon CO2, ammonia NH3, nitrogen N2, helium (He), argon (Ar) or mixed gases thereof.

The heater 700 is installed at the first electrode 210, and heats the first electrode 210 to control the temperature of the substrate 10 settled on a surface of the first electrode 210. In the present embodiment, the heater 700 is depicted as a structure separated from the first electrode 210, but not limited thereto, various structures, such as a structure in which the first electrode 210 and the heater 700 are integrally formed, are possible.

Shower head 800 is installed at the second electrode 220 and may uniformly spray the gas supplied by the gas supply unit 600 onto the substrate 10. In the present embodiment, the shower head 800 is depicted as a structure positioned on the second electrode 220, but not limited thereto, and various structures, such as a structure in which the shower head 800 is positioned below the second electrode 220, are possible.

Meanwhile, the interior surface of sidewall 100a of plasma chamber 100, opposed electrodes 200, shower head 800, etc. may be made of non-ferromagnetic material that does not shield the magnetic field B. Therefore, since the magnetic field B formed inside the plasma chamber 100 by the solenoid coil 300 is not shielded by other components, the magnetic field B can be applied to the plasma P without loss.

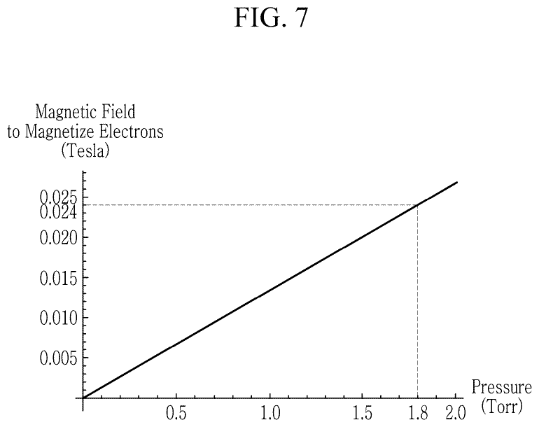

FIG. 7 is a graph of the minimum magnetic field strength required to magnetize electrons inside the plasma chamber according to the process pressure inside the plasma chamber in the plasma generation apparatus of FIG. 2.

As shown in FIG. 7, the minimum magnetic field strength required to magnetize electrons inside the plasma chamber 100 may be proportional to the process pressure inside the plasma chamber 100.

For example, if the process pressure inside the plasma chamber 100 is 1.8 Torr, a magnetic field B with a strength of 0.024 Tesla or greater must be formed inside the plasma chamber 100.

In order to meet the minimum magnetic field strength required depending on the pressure inside the plasma chamber 100, the length (L) of the solenoid coil 300, the number of turns (N) of the solenoid coil 300, the strength of the DC current DC supplied to the solenoid coil 300, and the thickness of the solenoid coil 300 may be adjusted.

Meanwhile, in the aforementioned embodiment, the solenoid coil is positioned on the outer surface of the sidewall of the plasma chamber, but another embodiment that the solenoid coil is positioned on the inner surface of the sidewall of the plasma chamber is also possible.

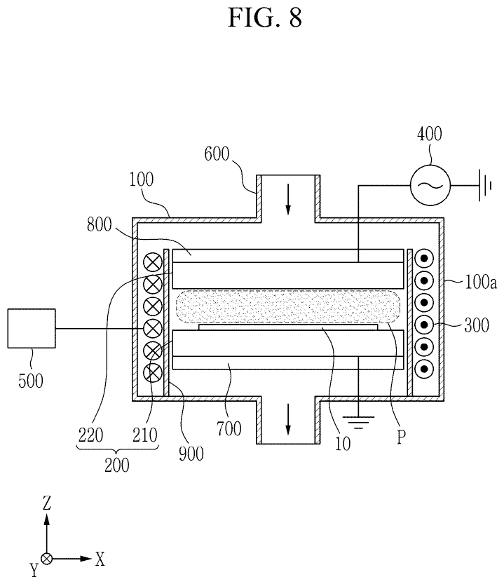

Below, a plasma generating apparatus according to another embodiment will be described in detail referring to FIG. 8.

FIG. 8 is a schematic a cross-sectional view of a plasma generating apparatus according to another example embodiment.

Another embodiment illustrated in FIG. 8 is substantially the same as an embodiment illustrated in FIG. 1 to FIG. 4 except for the position of the solenoid coil 300, so a repeated description will be omitted.

As shown in FIG. 8, a plasma generating apparatus according to another embodiment includes a plasma chamber 100, a pair of opposed electrodes 200, a solenoid coil 300, an AC voltage applying unit 400, a DC current supply unit 500, a gas supply unit 600, a heater 700, a shower head 800, and a coil fixing member 900.

The plasma chamber 100 has a roughly cylindrical shape, and the sidewall 100a of the plasma chamber 100 may be a cylindrical surface.

The pair of opposed electrodes 200 is installed inside the plasma chamber 100, and an electric field E may be formed by applying AC voltage to generate plasma P.

The solenoid coil 300 surrounds the sidewall 100a of the plasma chamber 100 and may form a magnetic field B by applying a DC current DC. The solenoid coil 300 may be positioned on the inner surface of the sidewall 100a of the plasma chamber 100.

In this way, since the solenoid coil 300 is positioned on the inner surface of the sidewall of the plasma chamber 100 so as to form a magnetic field B directly on the opposed electrodes 200 without being shielded by other components such as the plasma chamber 100, a stronger magnetic field B can be formed using a smaller DC current DC compared to the case where the solenoid coil 300 is positioned on the outer surface of the sidewall of the plasma chamber 100.

The coil fixing member 900 is positioned inside the plasma chamber 100 and may be positioned between the sidewall 100a of the plasma chamber 100 and the edges of the opposed electrodes 200. For example, the coil fixing member 900 may surround the pair of opposed electrodes 200. The coil fixing member 900 may fix the solenoid coil 300. For example, the solenoid coil 300 may be disposed between the sidewall 100a of the plasma chamber 100 and the coil fixing member 900, and the solenoid coil 300 may be held in place by the sidewall 100a of the plasma chamber 100 and the coil fixing member 900. The coil fixing member 900 may be a flat piece of material comprised of a non-ferromagnetic material. Therefore, the magnetic field B by the solenoid coil 300 may be uniformly formed inside the plasma chamber 100. In addition, since the coil fixing member 900 is made of a non-ferromagnetic material and does not shield the magnetic field B, the magnetic field B can be applied to the plasma P without loss.

The AC voltage applying unit 400 is electrically connected to the pair of opposed electrodes 200 and may apply AC voltage to the pair of opposed electrodes 200, and the DC current supply unit 500 is electrically connected to the solenoid coil 300 and may supply DC current DC to the solenoid coil 300.

In this way, by installing a pair of opposed electrodes 200 inside the plasma chamber 100, applying AC voltage to the opposed electrodes 200 to generate an electric field E between the opposed electrodes 200, installing a solenoid coil 300 on the sidewall 100a of the plasma chamber 100, and supplying DC current DC to the solenoid coil 300 to generate a magnetic field B parallel to the electric field E, the uniformity of the electron density of the plasma P adjacent to the substrate 10 can be improved.

Although the embodiments of the present disclosure have been described in detail above, the scope of the present disclosure is not limited thereto, and various modifications and improvements can be made by those skilled in the art using the basic concept of the present disclosure defined in the following claims, and they fall within the scope of the present disclosure.

<Description of symbols>

| | |
|---|---|
| 100: plasma chamber | 200: pair of opposed electrode |
| 300: solenoid coil | 400: AC voltage applying unit |
| 500: DC current supply unit | 600: gas supply unit |
| 700: heater | 800: shower head |
| 900: coil fixing member | |

What is claimed is:

1. A plasma generating apparatus comprising:
a plasma chamber;
a pair of opposed electrodes installed inside the plasma chamber and generating plasma by applying AC voltage to form an electric field; and
a solenoid coil surrounding a sidewall of the plasma chamber and supplying DC current to form a magnetic field,
wherein a part of the magnetic field formed by the solenoid coil penetrates the opposed electrode.

2. The plasma generating apparatus of claim 1, wherein a direction of the part of the magnetic field formed by the solenoid coil, which penetrates the opposed electrodes, is parallel to a direction of the electric field formed by the opposed electrodes.

3. The plasma generating apparatus of claim 1, wherein:
the plasma chamber has a cylindrical shape; and
the sidewall of the plasma chamber forms a cylindrical surface.

4. The plasma generating apparatus of claim 3, wherein:
the pair of opposed electrodes includes a first electrode and a second electrode which are opposed to each other in parallel; and
the first electrode and the second electrode have a circular disc shape.

5. The plasma generating apparatus of claim 4, wherein the solenoid coil is positioned on an outer surface of the sidewall of the plasma chamber.

6. The plasma generating apparatus of claim 4, wherein the solenoid coil is positioned on an inner surface of the sidewall of the plasma chamber.

7. The plasma generating apparatus of claim 6, further comprising:
a coil fixing member fixing the solenoid coil.

8. The plasma generating apparatus of claim 4, further comprising:
an AC voltage supply applying the AC voltage to the pair of opposed electrodes.

9. The plasma generating apparatus of claim 8, further comprising:
a DC current supply supplying the DC current to the solenoid coil.

10. The plasma generating apparatus of claim 4, wherein a minimum magnetic field strength required to magnetize electrons inside the plasma chamber is proportional to a pressure inside the plasma chamber.

11. The plasma generating apparatus of claim 4, wherein:
an inner surface of the sidewall of the plasma chamber is made of non-ferromagnetic material; and
the opposed electrodes are made of non-ferromagnetic material.

12. The plasma generating apparatus of claim 11, wherein the solenoid coil is made of a conductor material having resistance.

13. The plasma generating apparatus of claim 11, wherein the solenoid coil includes a superconducting solenoid coil made of a superconducting material having no resistance at a specific temperature.

14. The plasma generating apparatus of claim 4, further comprising:
a gas supply supplying gas to the plasma chamber;
a heater installed at the first electrode; and
a shower head installed at the second electrode and spraying a gas onto a substrate.

15. A plasma generating apparatus comprising:
a plasma chamber;
a pair of opposed electrodes installed inside the plasma chamber and generating plasma by applying AC voltage to form an electric field;
a solenoid coil surrounding a sidewall of the plasma chamber and supplying DC current to form a magnetic field;
an AC voltage supply applying the AC voltage to the pair of opposed electrodes; and
a DC current supply supplying the DC current to the solenoid coil,
wherein a direction of a part of the magnetic field formed by the solenoid coil, which penetrates the opposed electrodes, is perpendicular to surfaces of the opposed electrodes.

16. The plasma generating apparatus of claim 15, wherein the direction of the part of the magnetic field formed by the solenoid coil, which penetrates the opposed electrodes, is parallel to the direction of the electric field formed by the opposed electrodes.

17. The plasma generating apparatus of claim 16, wherein:
the plasma chamber has a cylindrical shape; and
the sidewall of the plasma chamber forms a cylindrical surface.

18. A plasma generating apparatus comprising:
a plasma chamber;
a pair of opposed electrodes installed inside the plasma chamber and generating plasma by applying AC voltage to form an electric field; and
a solenoid coil surrounding a sidewall of the plasma chamber and supplying DC current to form a magnetic field,
wherein an imaginary central axis of the solenoid coil is positioned on the same line as centers of the pair of opposed electrodes.

19. The plasma generating apparatus of claim 18, wherein a direction of a part of the magnetic field formed by the solenoid coil, which penetrates the opposed electrodes, is parallel to a direction of the electric field formed by the opposed electrodes.

20. The plasma generating apparatus of claim 19, wherein:
the pair of opposed electrodes includes a first electrode and a second electrode which are opposed to each other in parallel; and
the first electrode and the second electrode have a circular disc shape.
